(19) United States
(12) Patent Application Publication
(10) Pub. No.: US 2017/0068012 A1
(43) Pub. Date: Mar. 9, 2017

(54) MAGNETIC WAKE DETECTOR

(71) Applicant: Lockheed Martin Corporation, Bethesda, MD (US)

(72) Inventor: Bryan N. Fisk, Madison, AL (US)

(73) Assignee: Lockheed Martin Corporation, Bethesda, MD (US)

(21) Appl. No.: 15/003,396

(22) Filed: Jan. 21, 2016

Related U.S. Application Data
(60) Provisional application No. 62/214,792, filed on Sep. 4, 2015.

(51) Int. Cl. G01V 3/08; G01R 33/032

(52) U.S. Cl. CPC G01V 3/08; G01R 33/032

(57) ABSTRACT

Disclosed are systems, computer-readable mediums, and methods for detecting, using a magnetometer, a magnetic vector of a magnetic field. The magnetic vector of the magnetic field from the magnetometer is received by an electronic processor. A presence of a wake from a flying object is determined based upon the magnetic vector.

The present application claims the benefit of U.S. Provisional Application No. 62/214,792, filed Sep. 4, 2015, which is incorporated by reference herein in its entirety.

### FIELD

The present disclosure generally relates to sensors, and more particularly, to magnetic wake sensors that detect small magnetic fields caused by fast moving charged particles.

### BACKGROUND

Low flying objects can be difficult to detect with traditional radar. For example, cruise missiles can fly close to the ground, follow terrain, and constantly maneuver to avoid detection by radar and being shot down. Modern variants of cruise missiles can also be coated in radar absorbing material (RAM). These attributes can make cruise missiles difficult to find and track with traditional sensors. Tracking algorithms can often experience difficulty holding onto a target that maneuvers frequently, making it hard to attack. Flying at low altitude can make the missiles hard to detect against a backdrop of terrain, which is generally high clutter (e.g., noisy for the sensor). Being stealth and launched from long range can make the cruise missile even more difficult to defeat. Even airborne radars may have difficulty detecting and tracking low flying objects because of intense clutter issues involved with scanning down toward the Earth and trying to track a small, stealthy target.

Atomic-sized nitrogen-vacancy (NV) centers in diamond lattices can have excellent sensitivity for magnetic field measurement and enable fabrication of small magnetic sensors that can readily replace existing-technology (e.g., Hall-effect) systems and devices. Diamond NV (DNV) sensors can be maintained in room temperature and atmospheric pressure and can even be used in liquid environments. The DNV sensors may beorders of magnitude more sensitive than other technologies and can reduce magnetometer size, weight and power (SWAP).

### SUMMARY

Methods and configuration are described for detecting small magnetic fields caused by charged particles moving through a magnetic field. For example, the magnetic field caused by charged particles moving through the Earth's atmosphere can be detected. The charged particles can originate from an engine from a missile or aircraft or charged particles from a supersonic aircraft, such as a glider.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several implementations in accordance with the disclosure and are, therefore, not to be considered limiting of its scope, the disclosure will be described with additional specificity and detail through use of the accompanying drawings.

FIG. 1 illustrates a low altitude flying object in accordance with some illustrative implementations.

FIG. 2 illustrates a magnetic field detector in accordance with some illustrative implementations.

FIGS. 3A and 3B illustrate a portion of a detector array in accordance with some illustrative implementations.

FIG. 4 illustrates a computing system for implementing some features of some illustrative implementations.

### DETAILED DESCRIPTION

In some aspects of the present technology, methods and configurations are disclosed for detecting small magnetic fields generated by moving charged particles. For example, fast moving charged particles moving through the Earth's atmosphere create a small magnetic field that can be detected by the disclosed embodiments. Sources of charged particles include fast moving vehicles such as missiles, aircraft, supersonic gliders, etc. To detect the small magnetic fields, highly sensitive magnetometers (e.g., DNV sensors) may be used. DNV sensors can provide 0.01 μT sensitivity. These magnetometers can be as or more sensitive than the superconducting quantum interference device (SQUID) magnetometer (e.g., with femto-Tesla level measurement sensitivity).

As another example of a source of charged particles, a jet engine can create ions as a byproduct of the combustion process. Another example includes a super-sonic glider that generates a plasma field as the glider moves through the atmosphere. This plasma field can generate charged particles. The disclosed detectors can also detect magnetic fields underwater. Accordingly, torpedoes that are rocket propelled may create an ion flux. The charged particles, e.g., ions, are moving quite fast for a period of time until slowed down by the surrounding air. These fast moving ions (charged particles) can generate a low-level magnetic field in the atmosphere. This field can be detected by one or more detectors as described here within.

The subject technology can be used as an array of sensitive magnetic sensors (e.g., DNV sensors) to detect the magnetic fields created by charged particle sources, such as jet engine exhaust. A single detector can be used to detect the magnetic field that are generated over the detector. In one implementation, the range of a detector is 10 kilometers or less. In another implementation, the range of the detector is one kilometer. In this implementation, a single detector can detect a magnetic field within its 10 kilometer slant range. In another implementation, the magnetic sensors may be spread out along a coast or at a distance from some other areas of interest (e.g., critical infrastructure such as power plants, military bases, etc.). In addition, multiple lines of sensors can be used to allow the system to establish the missile trajectory. In one or more implementations, data from the magnetic sensors may be used in conjunction with data from passive acoustic sensors (e.g., to hear the signature whine of a jet engine) to improve the overall detection capabilities of the subject system. In some aspects, the sensors can be small enough to be covertly placed near an enemy air field to provide monitoring of jets as they take off or land (e.g., are at low altitudes). In various implementations, the detectors can be low power and persistent (e.g., always watching—without a manned crew). These detectors, therefore, can be used for covert (e.g., passive) surveillance based on the subject solution which cannot be detected, even by current stealth technology.

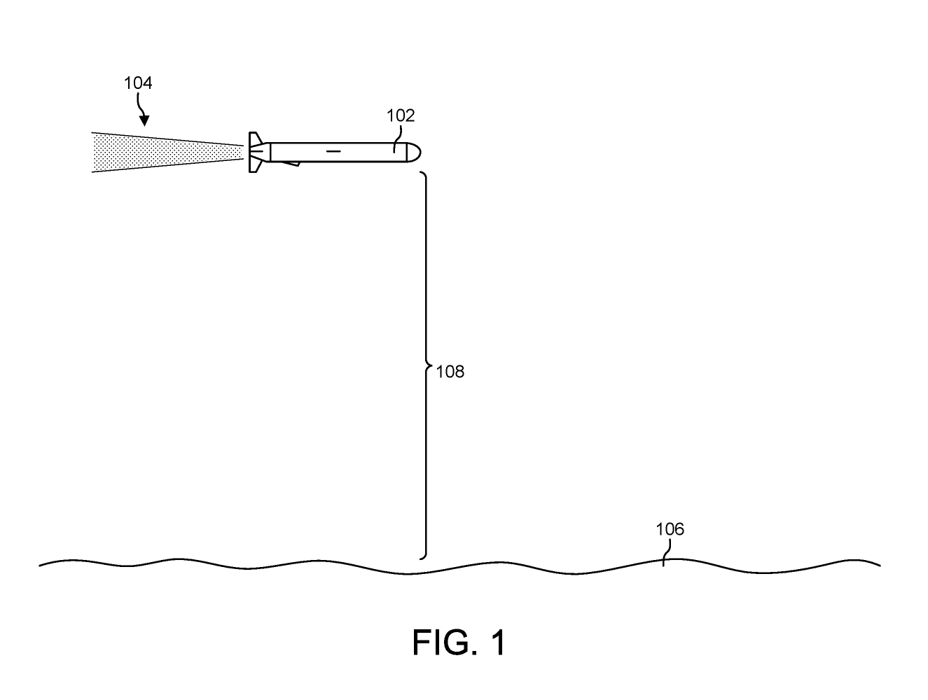

FIG. 1 illustrates a flying object 102 at low altitude 108 in accordance with some illustrative implementations. The flying object 102 can be a cruise missile, an aircraft, or a super-sonic glider. The flying object 102 can readily avoid radar tracking due to high clutter caused by terrain 106 and being stealth. Even airborne radars may not be able to detect and track these objects because of intense clutter issues involved with scanning down toward the Earth and trying to track a small, stealthy target. For example, high flying surveillance radar (e.g., AWACS or Hawkeye) can sometimes detect cruise missiles, but it is costly and has to be up in the air and have sufficient signal-to-noise ratio (SNR) to be able to operate in a high-clutter situation. Short-range radars may also provide detection capability, but require substantial power and, due to the low flight height of the missile, may be able to see the missile for an extremely brief period. The limited window of view-ability allows the missile to be easily missed by a ground based system (especially if rotating) in part because it would not persist in the field of view long enough to establish a track. The subject technology utilizes high sensitivity magnetic sensors, such as DNV sensors to detect weak magnetic fields generated by the fast movement of ions in the jet exhaust of cruise missiles. For example, a DNV sensor measures the magnetic field that acts upon the DNV sensor. When used on Earth, the DNV sensor measures the Earth's magnetic field, assuming there are no other magnetic fields affecting the Earth's magnetic field. The DNV measures a magnetic vector that provides both a magnitude and direction of the magnetic field. When another magnetic field is within range of the DNV sensor, the measured field changes. Such changes indicate the presence of another magnetic field.

When using a DNV sensor, each sample is a vector that represents the magnetic field affecting the DNV sensor. Accordingly, using measurements over time the positions in time and therefore, the path of an object can be determined. Multiple DNV sensors that are spaced out can also be used. For example, sensed magnetic vectors from multiple DNV sensors that are measured at the same time can be combined. As one example, the combined vectors can make up a quiver plot. Analysis, such as a Fourier transform, can be used to determine the common noise of the multiple measures. The common noise can then be subtracted out from various measurements.

One way measurements from a single or multiple DNV sensors can be used is to use the vectors in various magnetic models. For example, multiple models can be used that estimate the dimensions, mass, number of objects, position of one or more objects etc. The measurements can be used to determine an error of each of the models. The model with the lowest error can be identified as most accurately describing the objects that are creating the magnetic fields being measured by the DNV sensors. Alterations to one or more of the best models can then be applied to reduce the error in the model. For example, genetic algorithms can be used to alter a model in an attempt to reduce model error to determine a more accurate model. Once an error rate of a model is below a predetermined threshold, the model can help identify how many objects are generating the sensed magnetic fields as well as the dimensions and mass of the objects.

If the flying object 102 uses a combustion engine, exhaust 104 will be generated. The exhaust 104 can include charged particles that are moving at high speeds when exiting the flying object 102. These charged particles create a magnetic field that can be detected by the described implementations. As the Earth has a relatively static magnetic field, the detectors can detect disturbances or changes from the Earth's static magnetic field. These changes can be attributed to the flying object 102.

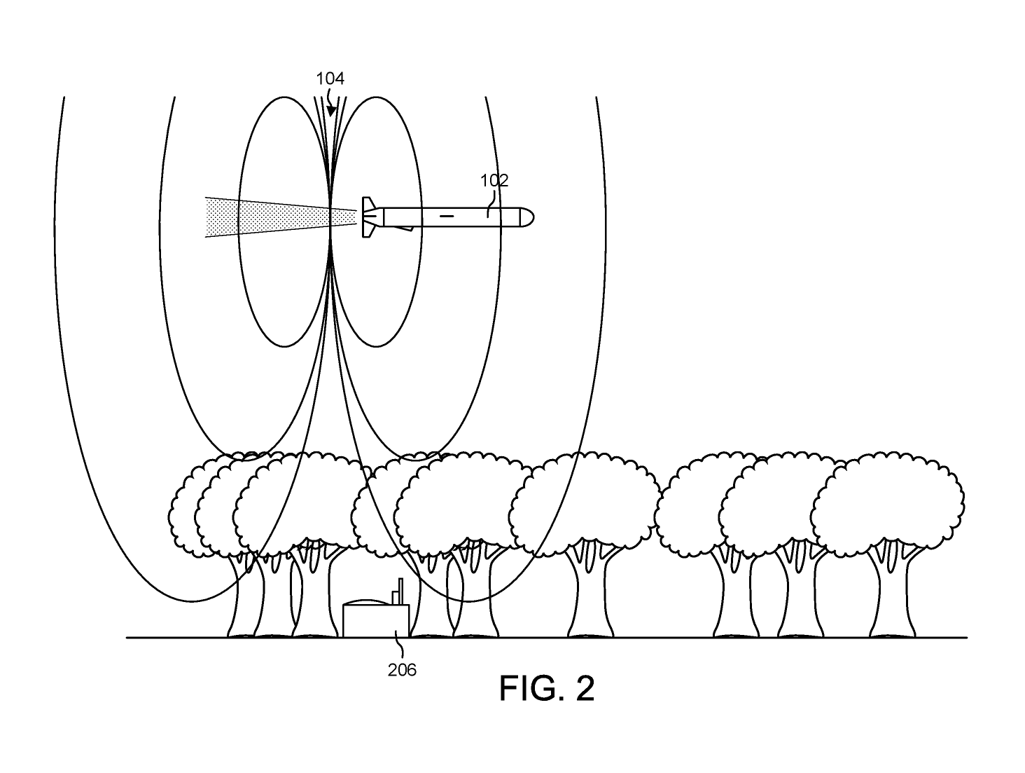

FIG. 2 illustrates a magnetic field detector in accordance with various illustrative implementations. A sensor 206 can detected a magnetic field 204 of a flying object 202 passing overhead the sensor 206. The sensor 206 can be passive in that the sensor 206 does not emit any signal to detect the flying object 202. Accordingly, the sensor 206 is passive and its use is not detectable by other sensors. For example a magnetic sensor such as a DNV-based magnetic sensor can detect magnetic field with high sensitivity without being detectable. A sensor network formed by a number of nodes equipped with magnetic sensors (e.g. DNV sensors) can be deployed, for example, along national borders, in buoys off the coast or in remote locations. For instance, a distant early warning line can be established near the Arctic Circle.

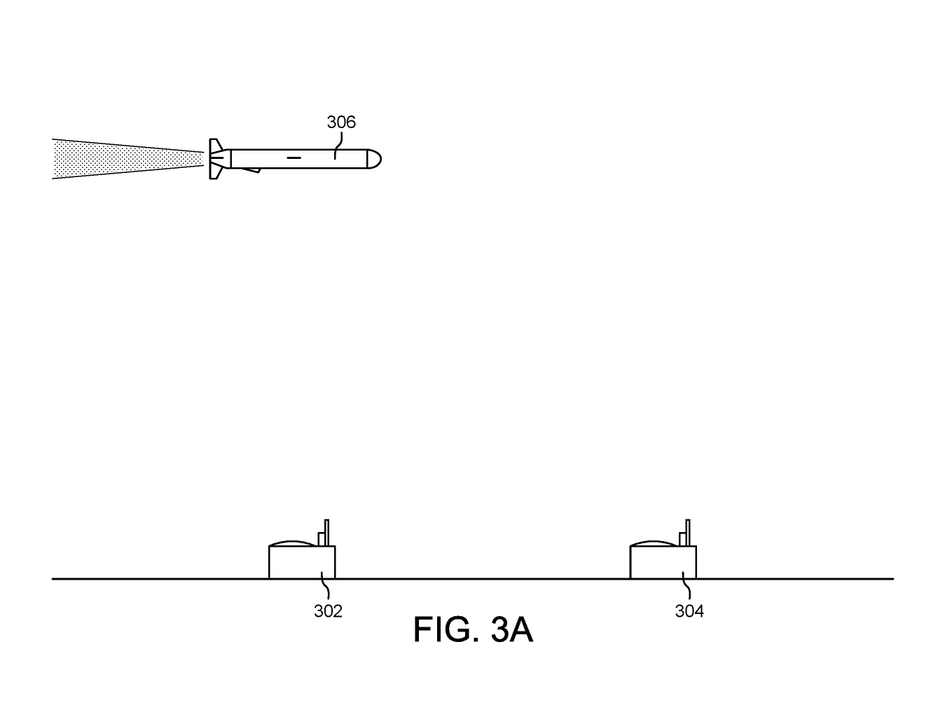

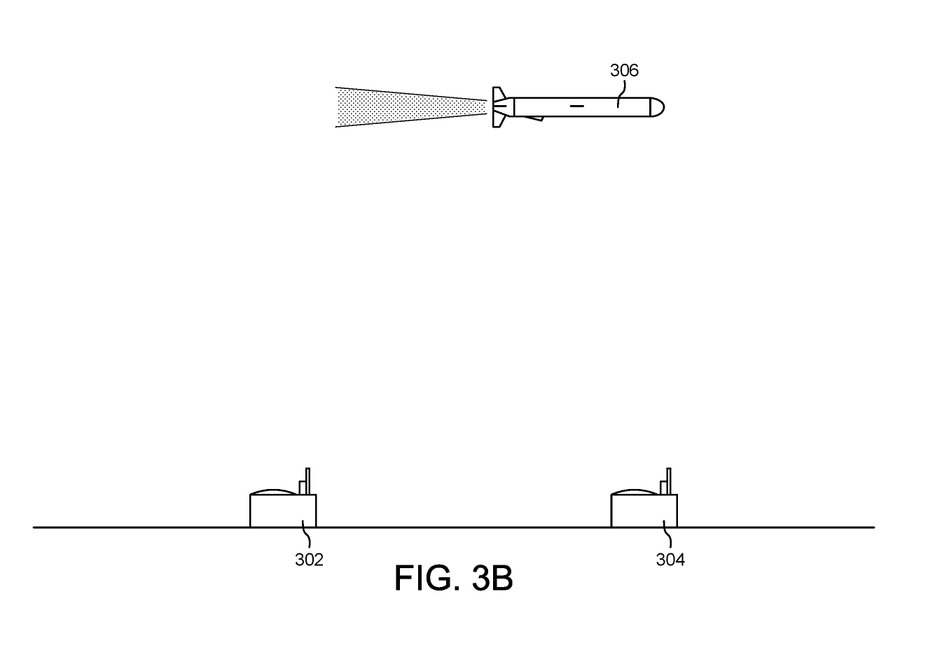

FIGS. 3a and 3b illustrate a portion of a detector array in accordance with various illustrative implementations. Detectors 302 and 304 can both detect the magnetic field generated by the flying object 306. Given an array of detectors located in a region, data from multiple detectors can be combined for further analysis. For example, data from the detectors 302 and 304 can be combined an analyzed to determine aspects such as speed and location of the flying object 306. As one example, at a first time shown in FIG. 3a, detector 302 can detect the magnetic field generated from the flying object 306. Detector 304 may not be able to detect this magnetic field or can detect the field but given the further distance the detected field will be weaker compared to the magnetic field detected by detector 302. This data from a single point of time can be used to calculate a position of the object 306. Data from a third detector can also be used to triangulate the position of the flying object 306. Data from a single detector can also be useful as this data can be used to detect a slant position of the flying object 306. The combined data can also be used to determine a speed of the flying object 306.

In addition, data from one or more detectors over time can be used. In FIG. 3b, the flying object 306 has continued its path. The magnetic field detected by detector 304 has increased in strength as the flying object approaches detector 304, while the magnetic field detected by detector 302 will be weaker compared to the magnetic field detected in FIG. 3a. The differences in strength are based upon the flying object being closer to detector 304 and further away from detector 302. This information can be used to determine a trajectory of the flying object 306.

As describe above, data from a single detector can be used to calculate a slant range of a flying object. The slant range can be calculated based upon a known intensity of the magnetic field of the flying object compared with the intensity of the detected field. Comparing these two values provides an estimate for the distance that the object is from the detector. The precise location, however, is not known, rather a list of possible positions is known, the slant range. The speed of the flying object can be estimated by comparing the detected magnetic field measurements over time. For example, a single detector can detect the magnetic field of the flying object over a period of time. How quickly the magnetic field increases or decreases in intensity as the flying object move toward or away, respectively, from the detector can be used to calculate an estimate speed of the flying object. Better location estimates can also be used by monitoring the magnetic field over a period of time. For example, monitoring the magnetic field from the first detection to the last detection from a single detector can be used to better estimate possible positions and/or the speed of the flying object. If the magnetic field was detected for a relatively long period of time, the flying object is either a fast moving object that flew closely overhead to the detector or is a slower moving object that few further away from the detector. The rate of change of the intensity of the magnetic field can be used to determine if the object is a fast moving object or a slow moving object. The possible positions of the flying object, therefore, can be reduced significantly.

The time history of the magnetic field can also be used to detect the type of flying object. Rocket propelled objects can have a thrust that is initially uniform. Accordingly, the charged particles will be moving in a uniform manner for a time after being propelled from the flying object. The detected magnetic field, therefore, will also have a detectable amount of uniformity over time when the range influence is taken into account. In contrast, hypersonic objects will lack this uniformity. For example, ions that leave a plasma field that surrounds the hypersonic object will not be ejected in a uniform manner. That is, the ions will travel in various different directions. The detected magnetic field based upon these ions will have a lot of variation that is not dependent on the range of the flying object. Accordingly, analysis of the intensity of the magnetic field, taking into account range influence, can determine if the magnetic field is uniform or has a large variation over time. Additional data can be used to refine this analysis. For example, calculating and determining a speed of an object can be used to eliminate possible flying objects that cannot fly at the determined speed. In addition, data from different types of detectors can be used. Radar data, acoustic data, etc., can be used in combination with detector data to eliminate possible types of flying objects.

Data combined from multiple sensors can also be used to more accurately calculate data associated with the flying object. For example, the time difference between when two separate detectors can be used to calculate a range of speeds and possible locations of the flying object. A first detector can first detect a flying object at a first time. A second detector can first detect the flying object at a second time. Using the known distance between the two detectors and the range of the two detectors, estimates of the speed and location of the flying object can be significantly enhanced compared to using data from a single detector. For example, the flying object is determined to be between two detectors rather than being on the opposite of the first detector. Further, the direction of the flying object can be deduced. The addition of a third detector allows for the location of the flying object to be triangulated.

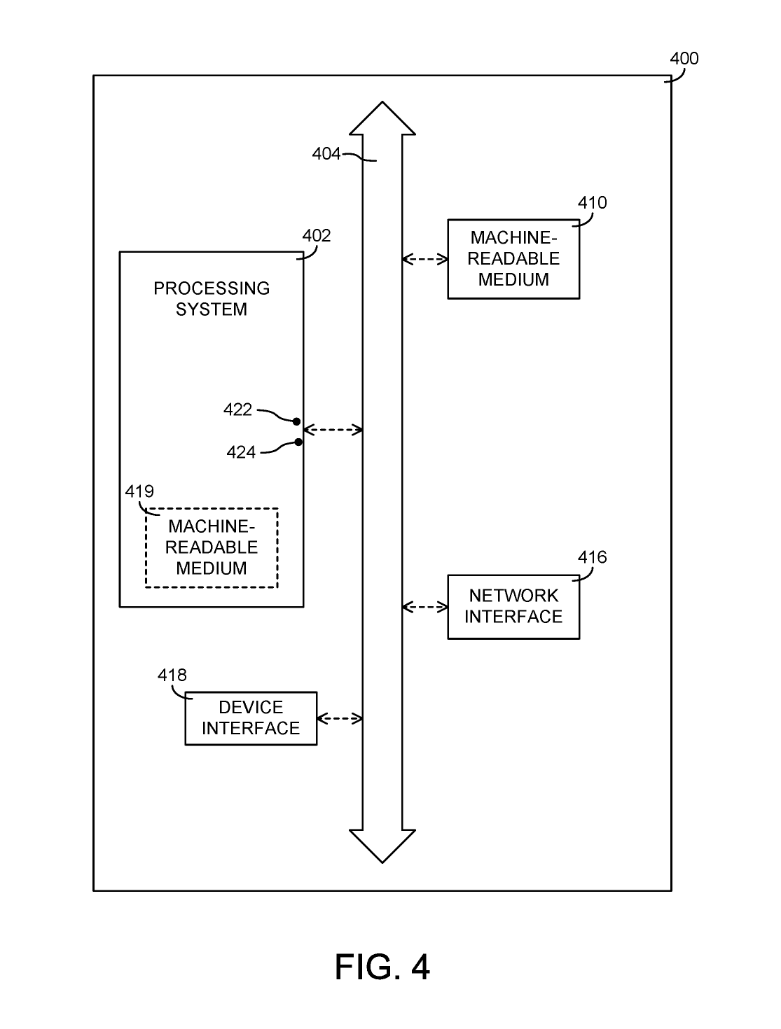

FIG. 4 is a diagram illustrating an example of a system 400 for implementing some aspects of the subject technology. The system 400 includes a processing system 402, which may include one or more processors or one or more processing systems. A processor can be one or more processors. The processing system 402 may include a general-purpose processor or a specific-purpose processor for executing instructions and may further include a machine-readable medium 419, such as a volatile or non-volatile memory, for storing data and/or instructions for software programs. The instructions, which may be stored in a machine-readable medium 410 and/or 419, may be executed by the processing system 402 to control and manage access to the various networks, as well as provide other communication and processing functions. The instructions may also include instructions executed by the processing system 402 for various user interface devices, such as a display 412 and a keypad 414. The processing system 402 may include an input port 422 and an output port 424. Each of the input port 422 and the output port 424 may include one or more ports. The input port 422 and the output port 424 may be the same port (e.g., a bi-directional port) or may be different ports.

The processing system 402 may be implemented using software, hardware, or a combination of both. By way of example, the processing system 402 may be implemented with one or more processors. A processor may be a general-purpose microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable device that can perform calculations or other manipulations of information.

A machine-readable medium can be one or more machine-readable media. Software shall be construed broadly to mean instructions, data, or any combination thereof, whether referred to as software, firmware, middleware, microcode, hardware description language, or otherwise. Instructions may include code (e.g., in source code format, binary code format, executable code format, or any other suitable format of code).

Machine-readable media (e.g., 419) may include storage integrated into a processing system such as might be the case with an ASIC. Machine-readable media (e.g., 410) may also include storage external to a processing system, such as a Random Access Memory (RAM), a flash memory, a Read Only Memory (ROM), a Programmable Read-Only Memory (PROM), an Erasable PROM (EPROM), registers, a hard disk, a removable disk, a CD-ROM, a DVD, or any other suitable storage device. Those skilled in the art will recognize how best to implement the described functionality for the processing system 402. According to one aspect of the disclosure, a machine-readable medium is a computer-readable medium encoded or stored with instructions and is a computing element, which defines structural and functional interrelationships between the instructions and the rest of the system, which permit the instructions' functionality to be realized. Instructions may be executable, for example, by the processing system 402 or one or more processors. Instructions can be, for example, a computer program including code.

A network interface 416 may be any type of interface to a network (e.g., an Internet network interface), and may reside between any of the components shown in FIG. 4 and coupled to the processor via the bus 404.

A device interface 418 may be any type of interface to a device and may reside between any of the components shown in FIG. 4. A device interface 418 may, for example, be an interface to an external device (e.g., USB device) that plugs into a port (e.g., USB port) of the system 400.

The foregoing description is provided to enable a person skilled in the art to practice the various configurations described herein. While the subject technology has been particularly described with reference to the various figures and configurations, it should be understood that these are for illustration purposes only and should not be taken as limiting the scope of the subject technology.

One or more of the above-described features and applications may be implemented as software processes that are specified as a set of instructions recorded on a computer readable storage medium (alternatively referred to as computer-readable media, machine-readable media, or machine-readable storage media). When these instructions are executed by one or more processing unit(s) (e.g., one or more processors, cores of processors, or other processing units), they cause the processing unit(s) to perform the actions indicated in the instructions. In one or more implementations, the computer readable media does not include carrier waves and electronic signals passing wirelessly or over wired connections, or any other ephemeral signals. For example, the computer readable media may be entirely restricted to tangible, physical objects that store information in a form that is readable by a computer. In one or more implementations, the computer readable media is non-transitory computer readable media, computer readable storage media, or non-transitory computer readable storage media.

In one or more implementations, a computer program product (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

While the above discussion primarily refers to microprocessor or multi-core processors that execute software, one or more implementations are performed by one or more integrated circuits, such as application specific integrated circuits (ASICs) or field programmable gate arrays (FPGAs). In one or more implementations, such integrated circuits execute instructions that are stored on the circuit itself.

In some aspects, the subject technology is related to sensors, and more particularly to magnetic wake cruise missile detector. In some aspects, the subject technology may be used in various markets, including for example and without limitation, advanced sensors, low counter and/or low observables, and systems integration markets.

The description of the subject technology is provided to enable any person skilled in the art to practice the various embodiments described herein. While the subject technology has been particularly described with reference to the various figures and embodiments, it should be understood that these are for illustration purposes only and should not be taken as limiting the scope of the subject technology.

There may be many other ways to implement the subject technology. Various functions and elements described herein may be partitioned differently from those shown without departing from the scope of the subject technology. Various modifications to these embodiments may be readily apparent to those skilled in the art, and generic principles defined herein may be applied to other embodiments. Thus, many changes and modifications may be made to the subject technology, by one having ordinary skill in the art, without departing from the scope of the subject technology.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various embodiments described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

What is claimed is:

1. A system for detecting a magnetic field comprising:
a magnetometer configured to detect a magnetic vector of a magnetic field;
one or more electronic processors configured to:
receive the magnetic vector of the magnetic field from the magnetometer; and
determine a presence of a wake, based upon the magnetic vector, from a flying object based upon the magnetic field.

2. The system of claim 1, wherein to determine the presence of the wake from the flying object the one or more electronic processors are further configured to:
determine a difference between the magnetic vector of the magnetic field with a vector of the magnetic field of the earth, wherein the difference is used to determine the presence of the wake.

3. The system of claim 1, wherein the magnetometer has a sensitivity of 0.01 μT.

4. The system of claim 1, wherein the range of the magnetometer is one kilometer.

5. The system of claim 1, wherein the one or more electronic processors are further configured to receive a plurality of magnetic vector values over time.

6. The system of claim 5, wherein the one or more electronic processors are further configured to calculate a speed of the flying object based upon the plurality of magnetic vectors.

7. The system of claim 5, wherein the one or more electronic processors are further configured to:
calculate a plurality of possible locations of the flying object based upon the magnetic vector;
eliminate a subset of the possible locations based upon the plurality of magnetic vectors.

8. The system of claim 5, wherein the one or more electronic processors are further configured to:
calculate an uniformity of the magnetic field over time based upon the plurality of magnetic vectors; and
identify the flying object based upon the uniformity of the magnetic field over time.

9. The system of claim 8, wherein the flying object is a missile.

10. The system of claim 8, wherein the flying object is a hypersonic glider.

11. The system of claim 8, wherein the flying object is a torpedo.

12. The system of claim 1, wherein the magnetometer is passive.

13. A method comprising:
detecting, using a magnetometer, a magnetic vector of a magnetic field;
receiving, at one or more electronic processors, the magnetic vector of the magnetic field from the magnetometer; and
determining a presence of a wake, based upon the magnetic vector, from a flying object based upon the magnetic field.

14. The method of claim 13, wherein determining the presence of the wake from the flying object comprises determining a difference between the magnetic vector of the magnetic field with a vector of the magnetic field of the earth, wherein the difference is used to determine the presence of the wake.

15. The method of claim 13, wherein the magnetometer has a sensitivity of 0.01 μT.

16. The method of claim 13, wherein the range of the magnetometer is one kilometer.

17. The method of claim 13, further comprising receiving a plurality of magnetic vectors over time.

18. The method of claim 17, further comprising calculating a speed of the flying object based upon the plurality of magnetic vectors.

19. The method of claim 17, further comprising:
calculating a plurality of possible locations of the flying object based upon the magnetic vector;
eliminating a subset of the possible locations based upon the plurality of magnetic vectors.

20. The method of claim 17, further comprising:
calculating an uniformity of the magnetic field over time based upon the plurality of magnetic vectors; and
identifying the flying object based upon the uniformity of the magnetic field over time.

21. The method of claim 20, wherein the flying object is a missile.

22. The method of claim 20, wherein the flying object is a hypersonic glider.

23. The method of claim 20, wherein the flying object is a torpedo.

24. The method of claim 13, wherein the magnetometer is passive.

25. A non-transitory computer-readable medium having instructions stored thereon, that when executed by a computing device cause the computing device to perform operations comprising:
receiving a vector of magnetic field from a magnetometer; and
determining a presence of a wake, based upon the vector, from a flying object that based upon the magnetic field.

26. The non-transitory computer-readable medium of claim 25, wherein determining the presence of the wake from the flying object comprises determining a difference between the magnetic vector of the magnetic field with a vector of the magnetic field of the earth, wherein the difference is used to determine the presence of the wake.

27. The non-transitory computer-readable medium of claim 25, wherein the magnetometer has a sensitivity of 0.01 μT.

28. The non-transitory computer-readable medium of claim 25, wherein the range of the magnetometer is one kilometer.

29. The non-transitory computer-readable medium of claim 25, wherein the operations further comprise receiving a plurality of magnetic vectors over time.

30. The non-transitory computer-readable medium of claim 29, wherein the operations further comprise calculating a speed of the flying object based upon the plurality of magnetic vectors.

31. The non-transitory computer-readable medium of claim 29, wherein the operations further comprise:
calculating a plurality of possible locations of the flying object based upon the magnetic vector;
eliminating a subset of the possible locations based upon the plurality of magnetic vectors.

32. The non-transitory computer-readable medium of claim 29, wherein the operations further comprise:
calculating an uniformity of the magnetic field over time based upon the plurality of magnetic vectors; and
identifying the flying object based upon the uniformity of the magnetic field over time.

33. The non-transitory computer-readable medium of claim 32, wherein the flying object is a missile.

34. The non-transitory computer-readable medium of claim 32, wherein the flying object is a hypersonic glider.

35. The non-transitory computer-readable medium of claim 32, wherein the flying object is a torpedo.

36. The non-transitory computer-readable medium of claim 25, wherein the magnetometer is passive.

37. A system comprising:
a first magnetometer configured to detect a first magnetic vectors of a magnetic field;
a second magnetometer configured to detect a second magnetic vector of the magnetic field;
one or more electronic processors configured to:
receive the magnetic vectors of the magnetic field from the first and second magnetometers; and
determine a presence of a wake, based upon the magnetic vectors, from a flying object based upon the magnetic vectors.

38. The system of claim 37, wherein to determine the presence of the wake from the flying object the one or more electronic processors are further configured to:
determine differences between the vectors of the magnetic fields with a vector of the magnetic field of the earth, wherein the differences are used to determine the presence of the wake.

39. The system of claim 37, wherein the magnetometer has a sensitivity of 0.01 μT.

40. The system of claim 37, wherein the range of the magnetometer is one kilometer.

41. The system of claim 37, wherein the one or more electronic processors are further configured to:
receive a first plurality of magnetic vectors over time from the first magnetometer; and
receive a second plurality of magnetic vectors over time from the second magnetometer.

42. The system of claim 41, wherein the one or more electronic processors are further configured to calculate a speed of the flying object based upon the plurality of magnetic vectors from the first and second magnetometers.

43. The system of claim 41, wherein the one or more electronic processors are further configured to:
calculate a plurality of possible locations of the flying object based upon the first magnetic vector;
eliminate a first subset of the possible locations based upon the second magnetic vector;
eliminate a subset of the possible locations based upon the plurality of magnetic vectors from the first and second magnetometers.

44. The system of claim 41, wherein the one or more electronic processors are further configured to:
calculate an uniformity of the magnetic field over time based upon the plurality of magnetic vectors from the first and second magnetometers; and
identify the flying object based upon the uniformity of the magnetic field over time.

45. The system of claim 44, wherein the flying object is a missile.

46. The system of claim 44, wherein the flying object is a hypersonic glider.

47. The system of claim 44, wherein the flying object is a torpedo.

48. The system of claim 37, wherein the magnetometer is passive.

49. The system of claim 37, further comprising:
a third magnetometer configured to detect a third magnetic vector of the magnetic field; and
triangulate a location of the flying object based upon the first magnetic vector, the second magnetic vector, and the third magnetic vector.
